(19) United States
(12) Patent Application Publication
(10) Pub. No.: US 2024/0418787 A1
(43) Pub. Date: Dec. 19, 2024

(54) METHOD FOR DETERMINING THE STATE OF CHARGE OF AN ELECTRICAL ENERGY STORAGE UNIT

(71) Applicant: Robert Bosch GmbH, Stuttgart (DE)

(72) Inventor: Holger Claus, Stuttgart (DE)

(21) Appl. No.: 18/735,434

(22) Filed: Jun. 6, 2024

(30) Foreign Application Priority Data
Jun. 15, 2023 (DE) 10 2023 205 578.3

(51) Int. Cl. G01R 31/388; G01R 19/12; G01R 31/367

(52) U.S. Cl. CPC G01R 31/388; G01R 19/12; G01R 31/367

(57) ABSTRACT

A method for determining the state of charge of an electrical energy storage unit. In one example, the method includes approximately determining a state of charge of the electrical energy storage unit, so that the state of charge is known at least with a predefined tolerance; transmitting a first control command for charging and/or discharging the electrical energy storage unit depending on the approximate state of charge determined; and determining a rate of change of the open circuit voltage of the electrical energy storage unit during charging and/or discharging. When the predefined rate of change exceeds or falls below a predefined first rate of change, a first state of charge value is determined depending on the determined rate of change of the open circuit voltage during charging and/or discharging.

### BACKGROUND

The present invention is based on a method for determining the state of charge of an electrical energy storage unit.

The state of charge (SOC) of an electrical energy storage unit, e.g., a rechargeable cell, can be determined by measuring the open circuit voltage (OCV) or by integrating the measured current (coulomb counting). Tolerances in the current measurement, for example, mean that coulomb counting only provides sufficiently accurate SOC values during operation and only for a limited time. Therefore, regular correction by measuring the open-circuit voltage is required. In addition, coulomb counting requires knowledge of an initial SOC value.

### SUMMARY

Depending on the type of electrical energy storage unit, for example with NMC battery cells, it may be possible to determine the state of charge by measuring the open-circuit voltage over the entire state of charge range. In other electrical energy storage units, such as lithium iron phosphate battery cells, the open-circuit voltage curve is so flat over a wide range of the state of charge that it is not possible to determine the SOC in a meaningful way due to measuring tolerances. A measurement of the open-circuit voltage only provides a sufficiently accurate SOC value when the battery cell is almost discharged or practically fully charged. If the lithium iron phosphate battery cell is two-thirds charged, a slight increase in voltage occurs, which can be used for a meaningful SOC determination. However, it is necessary to wait for a relaxation time before measuring the OCV voltage, as otherwise the shorter the relaxation time, the more the dynamics of the cell voltage will distort the measurement result. At room temperature, this relaxation time is at least 20 minutes. However, a significantly longer relaxation time must be assumed at low temperatures. Since the range in which the voltage increase occurs is relatively narrow and this range can shift with temperature and aging, multiple OCV measurements will be required in practical applications, which can take hours due to the relaxation times.

Alternatively, measurements in the low SOC range are also conceivable, but measurements in this low SOC range impair availability.

In order to determine the current cell capacity, i.e., the storage capacity of the battery cell, two SOC measurements are required at a significant distance from each other, so that a single SOC measurement is not sufficient for an almost fully charged battery. Moreover, it is difficult to determine the SOC of almost fully charged cells if several cells are connected in series, as different cell capacities and different charges mean that one cell has already reached the charge limit and cannot be charged any further, while other cells are not yet sufficiently charged for an SOC determination. This can be solved by equalizing the charge of individual cells, known as balancing, but this is very time-consuming.

Disclosed is a method for determining the state of charge of an electrical energy storage unit with the features of the independent claim.

In this method, a state of charge of the electrical energy storage unit is determined at least approximately so precisely that the state of charge is known at least with a predefined tolerance.

Depending on the approximate state of charge determined, a first control command for charging and/or discharging the electrical energy storage unit is transmitted. This can be done, for example, by an electrical control unit.

A rate of change of the open-circuit voltage of the electrical energy storage unit is determined during charging and/or discharging. If the determined rate of change exceeds or falls below a predefined first rate of change, a first state of charge value is determined depending on the determined rate of change of the open-circuit voltage during charging and/or discharging.

The method is advantageous because it allows the state of charge of the electrical energy storage unit to be determined accurately, even if there is a flat open-circuit voltage characteristic curve with only a few slight voltage changes. It is therefore particularly suitable for batteries or battery cells with lithium iron phosphate chemistry or another chemistry with a flat open-circuit voltage characteristic curve.

Further advantageous embodiments of the present invention are the subject matter of the dependent claims.

Conveniently, the first state of charge value is determined depending on an extreme point of the rate of change of the open-circuit voltage. This is advantageous as it allows the state of charge to be determined even more accurately, as an extreme point can be determined relatively precisely.

Conveniently, a predefined current value is not exceeded during charging and/or discharging. This is advantageous because the voltage gradient decreases as the magnitude of the current increases, which is detrimental to the accuracy of the determination. The method therefore ensures a sufficiently precise determination accuracy.

Conveniently, a second state of charge value is determined depending on the determined rate of change of the open-circuit voltage when a predefined second rate of change is exceeded. Furthermore, a current capacity of the electrical energy storage unit is determined depending on the first state of charge value, the second state of charge value, and an amount of charge converted between the two state of charge values during charging and/or discharging. This is advantageous as it allows the current capacity of the electrical energy storage unit, i.e., the amount of energy that can be stored, to be determined precisely.

Conveniently, the predefined first and the predefined second rate of change correspond to a predefined first state of charge and a predefined second state of charge. This is advantageous as there is thus a simple relationship between the rate of change and the state of charge and the state of charge can therefore be easily determined if the rate of change is known.

Conveniently, the first rate of change is in a range of 3 to 10 millivolts per state of charge step and the second rate of change is in a range of 25 to 75 millivolts per state of charge step. This enables reliable detection of the corresponding state of charge.

Another object of the invention is a device for determining the state of charge of an electrical energy storage unit, wherein the device comprises at least one means which is configured to carry out the step of a method according to the invention. The aforementioned advantages can thus be achieved. In particular, the means can be designed as an electronic battery management control unit.

Another object of the invention is a computer program comprising instructions which cause a device according to the invention to carry out all the steps of a method according to the invention. Thus, the aforementioned advantages can be realized.

Furthermore, it is an object of the invention to provide a machine-readable storage medium on which a computer program according to the invention is stored. Thus, the aforementioned advantages can be achieved and a simple distributability of the computer program according to the invention is ensured.

### BRIEF DESCRIPTION OF THE DRAWINGS

Advantageous embodiments of the invention are illustrated in the drawings and explained in more detail in the description below.

Shown are:

FIG. 1 the flowchart of a method according to an embodiment;

FIG. 2 a schematic illustration of an open-circuit voltage characteristic curve according to one embodiment;

FIG. 3 a schematic illustration of a gradient of the open-circuit voltage characteristic curve shown in FIG. 2 over the state of charge curve; and

FIG. 4 a schematic illustration of a device for determining the state of charge of an electrical energy storage unit according to one embodiment.

### DETAILED DESCRIPTION

In all of the figures, identical reference signs denote identical device components or identical method steps.

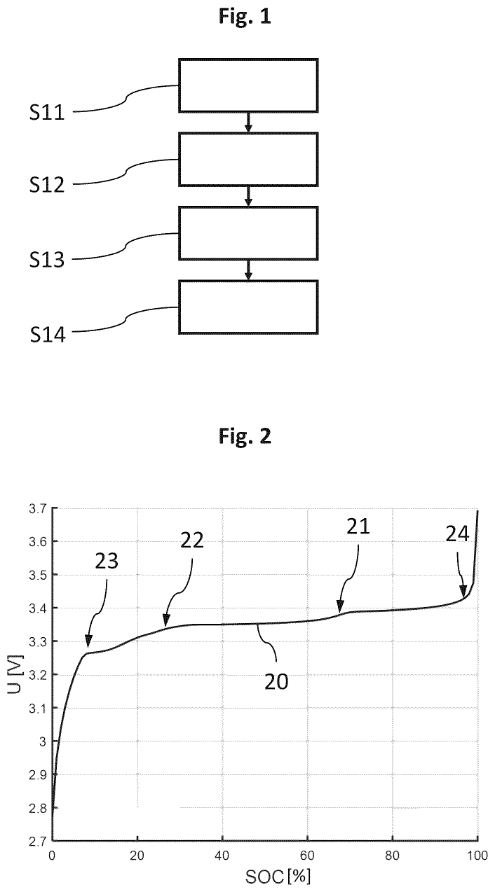

FIG. 1 shows a flowchart of a method according to the invention for determining the state of charge of an electrical energy storage unit according to one embodiment.

In a first step S11, an approximate state of charge of the electrical energy storage unit is determined so that it is possible, for example, to classify whether the electrical energy storage unit is less than two-thirds charged, i.e., has a state of charge of less than approx. 66%. The state of charge is thus known with at least a predefined tolerance.

Subsequently, in a second step S12, a first control command for charging and/or discharging the electrical energy storage unit is transmitted depending on the approximate state of charge determined. This can take place, for example, to a power electronic component with which the electrical energy storage unit is discharged, for example via a resistor or also during the drive of an electric motor.

In a third step S13, a rate of change of the open-circuit voltage of the electrical energy storage unit during charging and/or discharging is determined. This can be done, for example, by numerically differentiating the open-circuit voltage. For example, discrete values of the open-circuit voltage are determined and set in relation to the corresponding change in the state of charge.

In a fourth step S14, if a predefined first rate of change is exceeded by the rate of change determined in the third step S13, a first state of charge value is determined, wherein the determination is made depending on the determined rate of change of the open-circuit voltage during charging and/or discharging. This can be done, for example, by ensuring that the predefined first rate of change corresponds to a predefined first state of charge. The state of charge can thus be deduced from the rate of change. For example, the first rate of change can range from 3 to 10 millivolts per state of charge step. A state of charge is then assigned to this rate of change depending on the type of electrical energy storage unit.

FIG. 2 shows a schematic illustration of an open-circuit voltage characteristic curve 20 according to one embodiment. The open-circuit voltage characteristic curve 20 shows the typical curve for a lithium iron phosphate battery cell. There are four characteristic points at which the open-circuit voltage characteristic curve shows greater changes. At the first point 21, the corresponding electrical energy storage unit is approximately 66% charged. At the second point 22, the electrical energy storage unit is charged to approximately 25%. At the third point 23, the electrical energy storage unit is still approximately 10% charged and at the fourth point 24, the state of charge is approximately 98%.

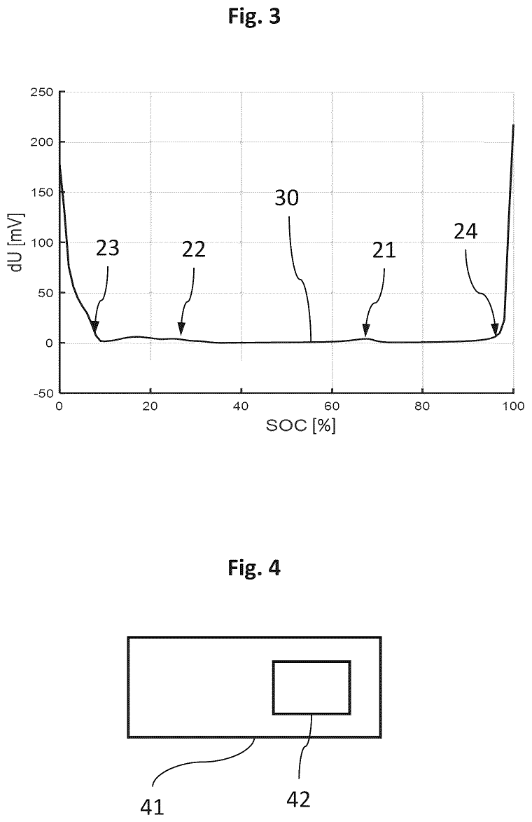

FIG. 3 shows a schematic illustration of a gradient 30 of the open-circuit voltage characteristic curve 20 shown in FIG. 2 over the state of charge curve. Here it is clear that at the points described in FIG. 2 there is a comparatively strong change in the open-circuit voltage. These points are so-called extreme points. At the first point 21 and the second point 22, the magnitude of a predefined first rate of change is in the range of 3 to 10 millivolts per state of charge step, for example. At the third point 23 and the fourth point 24, the magnitude of a predefined second rate of change is in the range from 25 to 75 millivolts per state of charge step.

The descriptions of FIGS. 2 and 3 show that if the state of charge of the electrical energy storage unit is approximately known, especially in the case of a lithium iron phosphate battery cell, the rate of change of the open-circuit voltage characteristic curve can be used to determine the state of charge of the electrical energy storage unit more accurately. For example, it is sufficient to know whether the electrical energy storage unit has a state of charge of more or less than 50%. The state of charge can, for example, be determined approximately by evaluating the open-circuit voltage, even with a short relaxation time. The approximate state of charge can then be further approximated by integrating the measured current, known as coulomb counting.

FIG. 4 shows a schematic illustration of a device 41 for determining the state of charge of an electrical energy storage unit according to one embodiment. The device 41 comprises an electronic computing unit 42, for example a battery management control unit or a computer, which is configured to carry out a method according to the invention.

1. A method for determining the state of charge of an electrical energy storage unit, said method comprising the following steps:
determining a state of charge of the electrical energy storage unit, so that the state of charge is known at least with a predefined tolerance;
transmitting a first control command for charging and/or discharging the electrical energy storage unit depending on the approximate state of charge determined;
determining a rate of change of the open circuit voltage of the electrical energy storage unit during charging and/or discharging; and
when the predefined rate of change exceeds or falls below a predefined first rate of change, a first state of charge value is determined depending on the determined rate of change of the open circuit voltage during charging and/or discharging.

2. The method according to claim 1, wherein the first state of charge value is determined depending on an extreme point of the rate of change of the open circuit voltage.

3. The method according to claim 1, wherein a predefined current value is not exceeded during charging and/or discharging.

4. The method according to claim 3, furthermore comprising:
determining a second state of charge value depending on the determined rate of change of the open circuit voltage when a predefined second rate of change is exceeded;
determining a current capacity of the electrical energy storage unit depending on the first state of charge value, the second state of charge value, and an amount of charge converted between the two state of charge values during charging and/or discharging.

5. The method according to claim 1, wherein the predefined first rate of change and the predefined second rate of change correspond to a predefined first state of charge and a predefined second state of charge.

6. The method according to claim 1, wherein the first rate of change is in a range of 3 to 10 millivolts per state of charge step and the second rate of change is in a range of 25 to 75 millivolts per state of charge step.

7. A device (41) for determining the state of charge of an electrical energy storage unit, comprising an electronic battery management controller, which is configured to carry out the steps of the method according to claim 1.

8. A non-transitory, computer-readable storage medium containing instructions that when executed by a computer cause the computer to determine a state of charge of an electrical energy storage unit, by:
determining a state of charge of the electrical energy storage unit, so that the state of charge is known at least with a predefined tolerance;
transmitting a first control command for charging and/or discharging the electrical energy storage unit depending on the approximate state of charge determined;
determining a rate of change of the open circuit voltage of the electrical energy storage unit during charging and/or discharging; and
when the predefined rate of change exceeds or falls below a predefined first rate of change, a first state of charge value is determined depending on the determined rate of change of the open circuit voltage during charging and/or discharging.
